(19) United States
(12) Patent Application Publication
(10) Pub. No.: US 2005/0133252 A1
(43) Pub. Date: Jun. 23, 2005

(54) Printed circuit board noise suppression device and method of manufacturing

(76) Inventors: Peter Ajersch, Gloucester (CA); Daryl Bender, Kanata (CA); Geoffrey Skanes, Richmond (CA)

Correspondence Address: SMART & BIGGAR/FETHERSTONHAUGH & CO.;P.O. BOX 2999, STATION D, 900-55 METCALFE STREET, OTTAWA, ON, K1P5Y6, CA

(21) Appl. No.: 10/740,411

(22) Filed: Dec. 22, 2003

(51) Int. Cl. H05K 1/16

(52) U.S. Cl. 174/260

(57) ABSTRACT

A noise suppression device for a printed circuit board suppresses both radiated noise and conducted noise. An electrically conductive sub-enclosure at least partially encloses a portion of the PCB, and a divider extends electrically into a surface of the PCB along an edge of the enclosed portion. Electrical signal filters carried by the sub-enclosure filter signals to be transferred through the sub-enclosure.

### FIELD OF THE INVENTION

This invention relates generally to electrical and electromagnetic noise suppression and, in particular, to suppressing noise on printed circuit boards (PCBs).

### BACKGROUND

PCBs used in noise-sensitive applications such as telecommunications are often connected to, or incorporate, electronic devices that generate, transmit, or both generate and transmit electrical signals that contain undesirable radio frequencies (RF). Such signals are considered to be “noisy”, and the undesirable frequencies are commonly referred to as conducted noise or spurious emissions. Radiated noise is a consequence of conducted noise and is generated by the flow of these undesired electrical signals through electronic components and/or interconnecting wires or printed circuit board traces. Both conducted noise and radiated noise can adversely affect the operation of electronic devices or particular electronic components. This is commonly referred as electromagnetic interference (EMI).

One known technique for suppressing noise generated or transmitted on a PCB is to provide a metal enclosure, connected to a ground plane on an external device to which the PCB is connected, to substantially enclose the entire PCB. Such a metal enclosure acts as a shield, reducing the amount of radiated noise that propagates away from the PCB. Signal filters can be used in conjunction with such a shielded PCB to further reduce the noise generated, transmitted or radiated by the PCB by reducing conducted noise.

However, in many applications, external physical access to PCB components must be provided. Although openings in conventional shield enclosures allow access to such components as optical fiber, buttons, shafts, actuators, and circuit breakers, for example, these same openings tend to reduce shielding effectiveness. In order to prevent significant degradation of shield performance, such openings/apertures should be smaller than a maximum size, which is determined by a wavelength of radiated noise to be suppressed, and is generally on the order of λ/10-λ/1000, depending upon the amplitude of each noise spectral component, the number of apertures, the shape of the apertures and the desired amount of suppression. As such, conventional shield enclosures may not satisfy both noise suppression and external access requirements where relatively high-frequency noise is to be suppressed. This is particularly challenging when the dimensions of apertures likely to incur significant degradation are at the limit of common manufacturing capabilities or impart severe design constraints at the outset. This is often the case when attempting to suppress noise at frequencies at or over 1 GHz, for example.

### SUMMARY OF THE INVENTION

A noise suppression device for a PCB according to one aspect of the invention includes an electrically conductive sub-enclosure configured to at least partially enclose a portion of the PCB, a divider configured to extend electrically into a surface of the PCB along an edge of the at least partially enclosed portion, and electrical signal filters mounted on the sub-enclosure. The noise suppressing device thus suppresses both conducted noise and radiated noise but encloses only a section of a PCB.

In some embodiments, the divider is integrated with the sub-enclosure, or with one section of the sub-enclosure. The enclosed section of the PCB may be a clean side or a noisy side of the noise suppression device.

The divider may physically extend onto the circuit board, as a surface mounted component in electrical contact with conductive material in a plurality of through holes in the PCB, for example, or into the PCB. In one embodiment, the divider includes pins, with pin spacing being less than a maximum spacing based on a wavelength of radiated noise to be suppressed. The pins may be through hole pins or compliant pins.

In one embodiment, the sub-enclosure includes multiple sub-enclosure sections. Sub-enclosure sections may be adapted for mounting on surfaces of the PCB, including conductive surface plating or edge plating on the PCB, or on external devices in conjunction with which the PCB operates.

The invention also provides, in a further aspect, a conductive plate for use with a conductive sub-enclosure section for at least partially enclosing a section of a PCB and for connection to a suitable RF reference potential to suppress radiated noise. The conductive plate includes a divider configured to extend through the PCB to divide the partially enclosed section from a remainder of the PCB, and has openings for holding signal filters for suppressing conducted noise in electrical signals.

A device for suppressing noise on a PCB is also provided according to another aspect of the invention. The device includes means for at least partially enclosing a portion of the PCB, means for dividing the PCB into a noisy region and a clean region, the means for dividing extending electrically into a surface of the PCB, and means for filtering electrical signals to be transmitted from the noisy region to the clean region.

In accordance with a further aspect of the invention, a PCB includes an RF reference plane conductor and a noise suppression device in electrical contact with the RF reference plane conductor. The noise suppression device has a conductive sub-enclosure at least partially enclosing a portion of the PCB and forming a conductive barrier extending through the PCB, and filters for filtering electrical signals.

Yet another aspect of the invention provides a method of manufacturing a PCB. Drop-in components on a PCB substrate. A conductive divider is also placed on the PCB substrate to divide the PCB into separate areas. The conductive divider is configured for use with a conductive sub-enclosure to at least partially enclose one of the areas. The drop-in components and the conductive divider are then soldered onto the PCB substrate.

Other aspects and features of the present invention will become apparent, to those ordinarily skilled in the art, upon review of the following description of specific embodiments of the invention.

### BRIEF DESCRIPTION OF THE DRAWINGS

The invention will now be described in greater detail with reference to the accompanying diagrams, in which:

FIG. 1 is an isometric view of a section of a sub-enclosure according to an embodiment of the invention;

FIG. 2 is a side elevation of the sub-enclosure section of FIG. 1;

FIG. 3 is an isometric view of a section of a sub-enclosure according to another embodiment of the invention;

FIG. 4 is a side elevation of the sub-enclosure section of FIG. 3;

FIG. 5 is a cross-sectional view along line 5-5 of FIG. 4;

FIG. 6 is a top view of a base plate for use with the sub-enclosure section of FIGS. 3 and 4;

FIG. 7 is an exploded view of a noise suppression device according to a further embodiment of the invention;

FIG. 8 is an expanded view of the section 8-8 of FIG. 7;

FIGS. 9 and 10 are isometric views of a PCB having a noise suppression device in accordance with an embodiment of the invention; and

FIG. 11 is an isometric view of a backplane element and a PCB carrying a noise suppression device according to an embodiment of the invention.

### DETAILED DESCRIPTION OF THE PREFERRED EMBODIMENTS

As described briefly above, known enclosure-type noise shields that substantially enclose an entire PCB have inherent drawbacks, particularly where external access to PCB components is required. Noise suppression devices in accordance with aspects of the invention significantly mitigate the need for any openings in the shield and substantially reduce any noise from migrating through interconnections which traverse the shield boundary. This facilitates the necessary shielding and filtering while enclosing only a portion of a PCB, thereby providing physical access to all PCB components that are outside the noise suppression device. A noise suppression device preferably divides or partitions a PCB into “noisy” and “clean” sides or areas, such that physical access to components on a clean side of a noise suppression device, or alternatively on a noisy side of a noise suppression device, is not restricted by the noise suppression device.

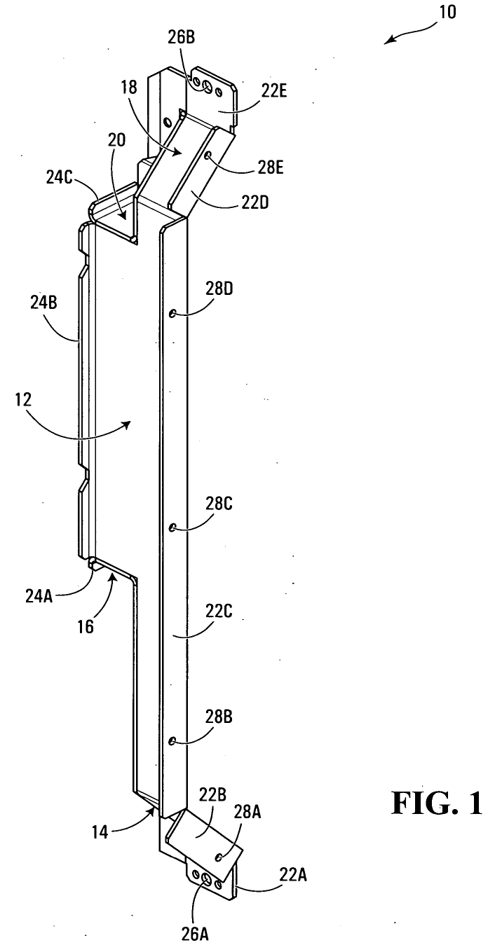

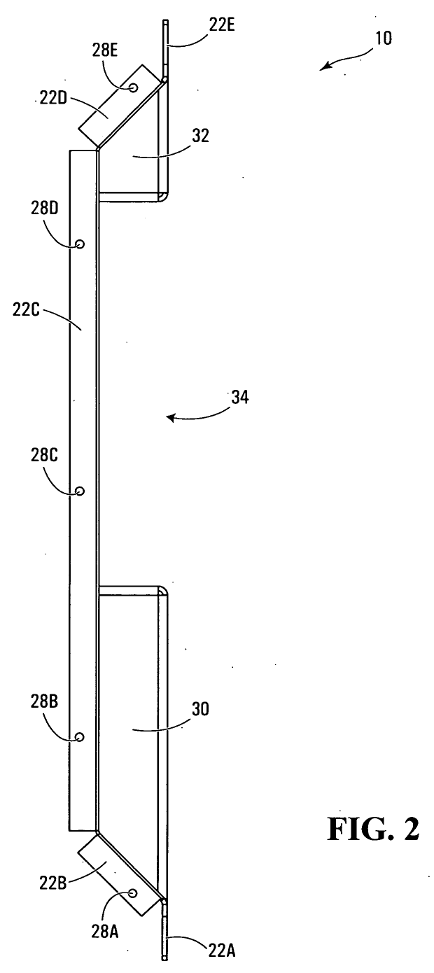

FIGS. 1 and 2 are, respectively, an isometric view and a side elevation of a section of a sub-enclosure according to an embodiment of the invention. The shape and structure of the sub-enclosure section 10 is intended solely for illustrative purposes, and the invention is in no way restricted thereto. It will be apparent to those skilled in the art that a sub-enclosure or any sections thereof may be sized and shaped in accordance with the physical requirements and restrictions of a particular device or environment in which the sub-enclosure will be implemented.

The sub-enclosure section 10 comprises a conductive material, preferably a metal such as aluminum or copper. A metal sub-enclosure section 10 may be fabricated by stamping from a metal sheet and subsequent forming of a stamped blank, casting, or tooling, for example. In other embodiments, conductive paints, coatings, or additives may be used in combination with non-conductive materials in the fabrication of the sub-enclosure section 10. A plastic sub-enclosure section 10 may be formed using a mould, for instance, and then painted with a conductive paint. Other suitable materials and fabrication methods will be apparent to those skilled in the art.

With reference to both FIGS. 1 and 2, the sub-enclosure section 10 comprises a plurality of walls 12, 14, 16, 18, 20, 30, and 32 for partially enclosing a portion of a PCB, and flanges or extensions 22 and 24, having bores 26 and 28 therein. As shown most clearly in FIG. 2, the walls are oriented in a plurality of planes and define an interior space or cavity 34 within which a portion of a PCB may be partially enclosed, as described in further detail below.

Depending upon the method of fabrication, the sub-enclosure section 10 is not necessarily a continuous component. Although such fabrication techniques as casting and moulding can produce a continuous sub-enclosure section 10, production of a continuous structure tends to be more difficult using other techniques. In a sub-enclosure section 10 formed from a stamped metal blank for instance, not all walls would be continuous with adjacent walls. Gaps between walls in a non-continuous structure that are smaller than a maximum allowable opening size, which is dependent upon the wavelength of radiated noise to be suppressed, should not significantly degrade the shielding effectiveness of the sub-enclosure section 10. Any larger gaps are preferably closed with conductive material, such as a patch of the material from which the sub-enclosure section 10 was fabricated or conductive solder or welding, for example. One or both of adjacent but discontinuous walls may also or instead incorporate mating structures such as flanges to provide for electrical contact between the adjacent walls and thereby close gaps in the structure of the sub-enclosure section 10.

As shown, the relative orientations of the walls of the sub-enclosure section 10 need not be consistent. In the sub-enclosure section 10, the walls 16 and 20 are substantially parallel to each other and substantially perpendicular to the wall 12. The walls 30 and 32 are similarly parallel to each other and substantially perpendicular to the wall 12. However, the walls 14 and 18 have different orientations relative to each other and to the wall 12. The walls 14 and 18 are not parallel to each other and are not perpendicular to the wall 12. Those skilled in the art will appreciate that the edges between adjacent walls of the sub-enclosure section 10 are substantially connected using any of a number of common techniques (soldering, welding, for example) to minimise gaps.

The sub-enclosure section 10 also includes a plurality of extensions or flanges 22 and 24 for abutting other sub-enclosure sections or portions of a PCB or a device in conjunction with which a PCB operates. The flanges 22A and 22E include bores 26A and 26B and possibly additional bores, not shown, for receiving fasteners for mounting the sub-enclosure section 10 to a PCB or other structure. The bores 28A, 28B, 28C, 28D and 28E in the flanges 22B, 22C, and 22D are similarly configured to receive fasteners for fastening the sub-enclosure section 10 to another sub-enclosure section. In one embodiment of the invention described in further detail below, the flanges 24A, 24B, and 24C contact a portion of an external device with which a PCB operates.

In one embodiment of the invention, a plurality of sub-enclosure sections are connected to form a sub-enclosure for at least partially enclosing a portion of a PCB. For example, the sub-enclosure section 10 is a first section of such a sub-enclosure. Other sections of the sub-enclosure are at least electrically, and preferably also physically, connected to the sub-enclosure section 10.

For example, where radiated noise is to be suppressed, a second sub-enclosure section abuts the flanges 28A, 28B, and 28C to close the cavity 34 along one side of the sub-enclosure section 10, and electrically contacts the sub-enclosure section 10 through a low-impedance connection, either directly or through an intermediate conductive material such as a conductive gasket. A conductive gasket between sections of a sub-enclosure may provide for more continuous and thus more effective and reliable electrical contact along entire surfaces of the sub-enclosure sections. A compressible gasket will typically conform more efficiently than the slight irregularities along the surface of abutting flanges and thereby mitigate residual gaps.

Further sub-enclosure sections may also be provided to substantially enclose components or portions of a PCB or device. These further sub-enclosure sections are either distinct sub-enclosure sections or provided as elements of a shielded PCB or device. In some embodiments, conductors on a shielded PCB, or a plurality of PCBS, and an external device form such further sub-enclosure sections for substantially enclosing a portion of a PCB.

As described above, a sub-enclosure at least partially encloses only a portion of a PCB or device, and thus partitions the PCB or device into a plurality of areas or regions.

According to an aspect of the invention, a noise suppression device includes a divider for dividing a PCB into a plurality of structurally connected but distinct portions or areas. The separate portions form elements of the clean side and the noisy side, either of which may be the portion that is at least partially enclosed by a sub-enclosure. The divider may be carried by, integral with, or a separate element configured for attachment to one or more sub-enclosure sections. An illustrative example of a divider is described in further detail below, and comprises a plurality of pins that extend into holes in the PCB. The pins and holes are preferably sized and spaced such that gaps between the pins are smaller than a maximum allowable opening size associated with radiated noise frequencies to be suppressed.

Those skilled in the art will appreciate that “noisy” and “clean” are not intended as absolute terms. Electronic components and electrical signals are rarely, if ever, totally clean. Electronic components that have RF current flowing through or over them may generate some noise, and electrical signals often include noise in the form of unwanted or unnecessary spectral components/frequencies. Similarly, practical noise shields and signal filters are not perfect, such that a clean side of a shield is not free from noise. In general, the clean side of a noise suppression device according to an embodiment of the invention has a lower level of noise than the noisy side. Indeed, those skilled in the art will appreciate the degree of isolation will be characterized by an amount, commonly expressed in decibels (dB), of shielding and filtering effectiveness.

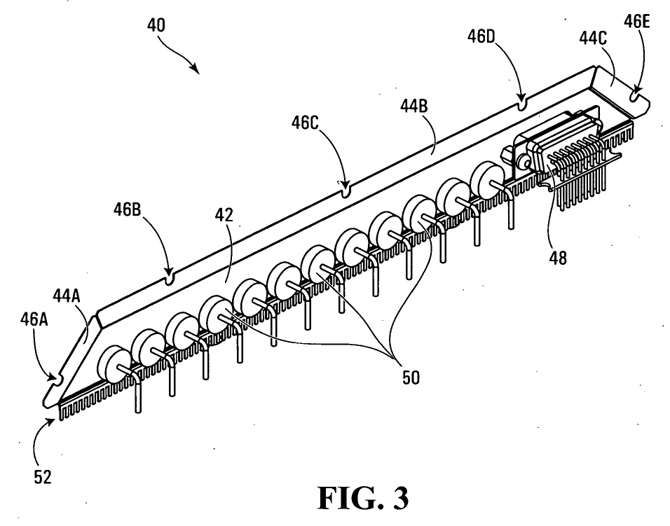

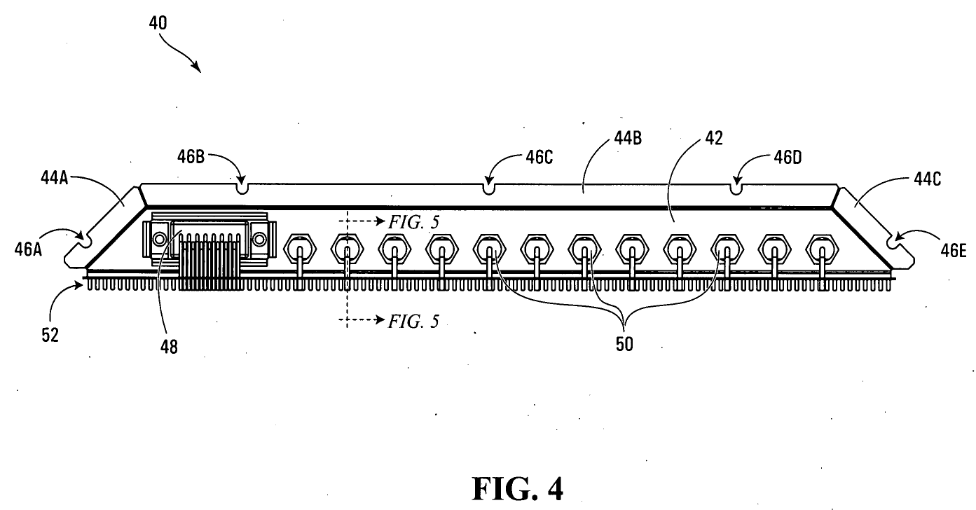

A conductive sub-enclosure as described above is suitable for implementations in which only radiated noise is to be suppressed. FIGS. 3 and 4 are an isometric view and a side elevation, respectively, of a section of a sub-enclosure according to another embodiment of the invention, which provides for suppression of both radiated noise and conducted noise. It will be apparent from FIGS. 1-4 that the sub-enclosure section 40 is adapted for use in conjunction with the sub-enclosure section 10. The sub-enclosure section 40 is thus a further illustrative example of a second sub-enclosure section as described generally above. However, the invention is in no way limited to the specific sub-enclosure sections 10 and 40. Sub-enclosure design is dependent upon noise suppression requirements, physical access requirements, and physical size and location restrictions, for example, of a particular PCB or device environment.

The sub-enclosure section 40 comprises a conductive plate 42 having extensions or flanges 44 with slots 46. Signal filters, including a filtered connector 48 and a plurality of electrical power filters 50, are carried by the plate 42.

The plate 42 is made of a conductive material or a non-conductive material with a conductive coating, such as any of the materials described above for the sub-enclosure section 10.

In an assembled sub-enclosure, the flanges 44A, 44B, and 44C abut the flanges 22B, 22C, and 22D of the sub-enclosure section 10, or an intermediate conductive gasket. The slots 46A, 46B, 46C, 46D, and 46E receive or accommodate fasteners that also pass through the corresponding bores 28A-28E of the sub-enclosure section 10. The slots 46 allow for a certain degree of misalignment with the bores 28 and adjustment of the relative positions of the sub-enclosure sections 10 and 40. In addition, as described in further detail below, the slots 46 simplify the assembly of a sub-enclosure where sections are mounted to a PCB at different manufacturing stages. However, it should be appreciated that sections of a sub-enclosure may incorporate slots, bores, or any combination thereof.

Such fasteners as nuts and bolts, screws, clamps, and rivets, for example, are preferred for attachment of sub-enclosure sections. However, other suitable fastening techniques will be apparent to those skilled in the art, including soldering or deformation of parts of one or both of the sub-enclosure sections, such as for heat staking or crimping, for instance. Embodiments of the invention in which alternative fastening techniques are employed need not necessarily incorporate such bores or slots.

When assembled, the sub-enclosure sections 10 and 40 form a sub-enclosure that at least partially encloses a portion of a PCB or a device. In accordance with an aspect of the invention, the sub-enclosure section 40 incorporates a divider, in the form of a plurality of pins 52, for dividing a PCB into a plurality of portions, including at least a clean side and a noisy side. The pins 52 are preferably either through-hole pins or compliant pins that extend into holes in the PCB. Through-hole pins are soldered into position in the holes, whereas compliant pins require no soldering. In a preferred embodiment, the pins extend from a first side of a PCB to a second, opposite side of the PCB via conductive through holes in a substrate of the PCB, and electrically connect with a ground plane conductor on the second side of the PCB.

In an alternate embodiment, the enclosure is surface mounted to a ground plane or RF reference plane along the periphery of the enclosure. Conductive “vias” or through holes connect this plane to a plane on the opposite side or an intermediate layer of the PCB which encloses the area encompassed by the enclosure.

Radiated noise suppression or shielding for a sub-enclosure comprising the sub-enclosure sections 10 and 40 is substantially as described above. The sub-enclosure forms a conductive barrier to reduce the amount of radiated noise that propagates from the noisy side of the sub-enclosure to the clean side of the sub-enclosure. The pins 52 and the holes in the PCB into which the pins extend are preferably sized and spaced such that gaps between the pins are smaller than a maximum allowable opening size for the radiated noise frequencies to be suppressed. By controlling the gap size in this manner, the conductive barrier effectively extends through the PCB between the clean side and the noisy side of the sub-enclosure.

In a sub-enclosure comprised of the sub-enclosure sections 10 and 40, the pins 52 are positioned only on the sub-enclosure section 40. The conductive barrier formed by the sub-enclosure and the pins therefore extends into and preferably through a PCB along a segment of an edge of the portion of the PCB that is at least partially enclosed by the sub-enclosure. In other embodiments, the conductive barrier extends into or through a PCB along an entire common edge between the at least partially enclosed portion and the remainder of the PCB, or possibly around an entire perimeter of the at least partially enclosed area.

The sub-enclosure section 40 also includes filters for filtering conducted noise from electrical signals, and may therefore be considered a filter plate. The filtered connector 48 and the plurality of filters 50 are illustrative examples of such filters. The electrical signals to be filtered may be power signals, control signals, data signals, or virtually any other type of electrical signal to be transferred from a noisy side of a noise suppressing device to a clean side of the device.

Filtered connectors are generally known in the art to which the present invention pertains. The connector 48 may be any such connector. In the example shown in FIGS. 3 and 4, the connector 48 is a 15-pin connector, although the invention is in no way limited to any specific size or type of connector.

Signal filters are also well-known. Common filter types that may be employed as the filters 50 include capacitive filters, inductive filters, and Pi filters, for example.

On filtered connections through the sub-enclosure section 40, noise components are filtered out of noisy input signals to provide filtered or clean output signals. In this manner, signals that are to be transmitted from the noisy side to the clean side of a noise suppression device are routed off a PCB, through a filtered connection in the noise suppression device, and then onto the clean side of the sub-enclosure. As described above, portion of a PCB that is partially enclosed by a sub-enclosure is either the clean side or the noisy side, and the filters 50 and the filtered connector 48 are implemented accordingly.

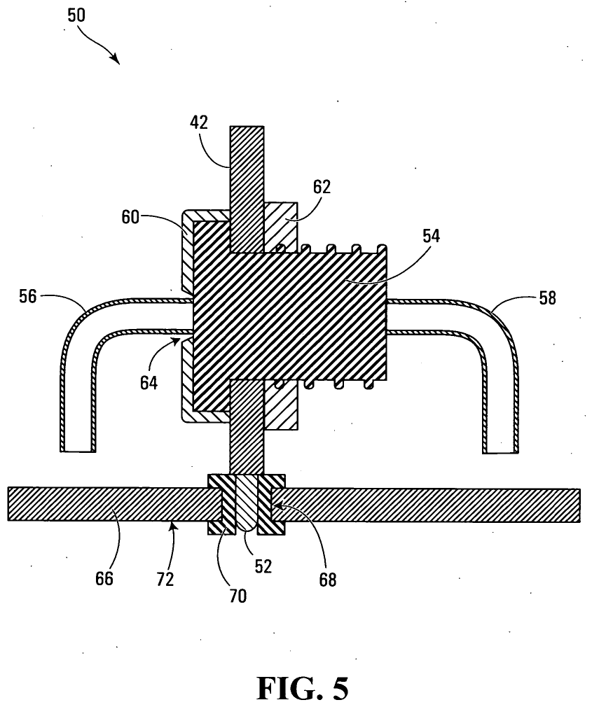

The filtered connector 48 and the filters 50 are accommodated in openings in the conductive plate 42. Given the typical sizes of such components, these openings may exceed a maximum allowable opening size, particularly where relatively high-frequency noise is to be suppressed. One possible solution to this potential problem is to locate the filtered connector 48 and the filters 50 on the noisy side of a noise suppression device. However, this creates a problem of transferring a filtered signal to the clean side. An alternative solution will now be described with reference to FIG. 5, which is a cross-sectional view along line 5-5 of FIG. 4.

FIG. 5 shows a filter 50, comprising a threaded filter component 54 held in an opening in the plate 42 with a conductive nut 62, preferably a metal nut. The filter component 54 has leads 56 and 58, which may, for example, include surface-mount pins, through-hole pins, compliant pins, or direct hardwire connections to other components of a PCB or an external device in conjunction with which a PCB operates.

The component 54 is preferably a conductive bushing or may be a non-conductive material with a conductive coating 60 applied to a surface thereof. The nut 62 and the conductive coating 60 provide conductive paths around the filter component 54 and the opening therein. As shown at 64, the coating 60 thereby reduces the effective size of a sub-enclosure opening. Although the conductive plate 42 includes an opening of sufficient size to required to accommodate the filter component 54, the conductive coating 60 overlaps and substantially closes the larger opening to a much smaller size. The opening 64 need only be large enough to accommodate the lead 56.

Conductive coatings may be provided on other surfaces of the filter component 54, and on one or more surfaces of the filtered connector 48. Where the filter component 54 is a capacitive filter, creating a conductive connection between the ground electrode of a capacitor in the filter component 54 and the conductive plate 42 may further reduce the effective opening size. Although not explicitly shown in FIG. 5, electrical contact between the conductive plate 42 and a conductive bushing or a conductive coating on a filter or filtered connector may be provided through a conductive gasket.

FIG. 5 also shows one of the pins 52 and a cooperating through hole 68 in a PCB 66. The pin 52 extends into the through hole 68 from a first side of the PCB 66 to a second, opposite side 72 of the PCB 66. In a preferred embodiment, each hole 68 is plated or stitched as shown at 70 to extend the conductive barrier through the PCB 66 to a second side of the PCB 66 as described above.

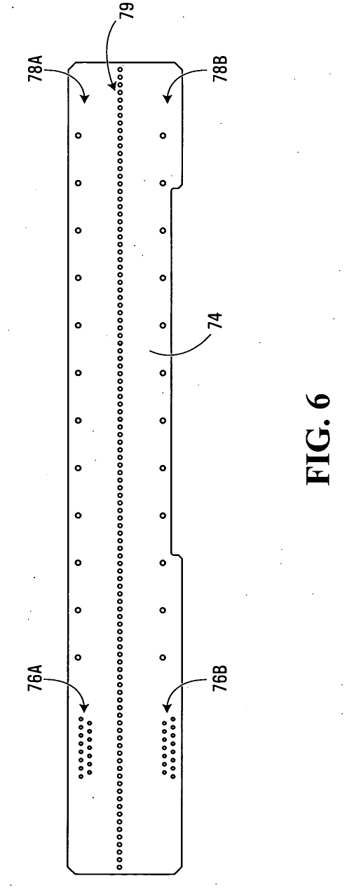

Insertion of components onto a PCB substrate in a direction that is substantially perpendicular to the substrate surface simplifies PCB fabrication. So-called “drop-in” components are therefore generally preferred. A primary challenge in adapting the sub-enclosure section 40 as a drop-in component is maintaining proper alignment of the leads for the filtered connector 48 and the filters 50. In one embodiment, sub-enclosure section 40 is itself assembled on a non-conductive substrate or base plate. FIG. 6 is a top view of a base plate for use with the sub-enclosure section 40 of FIGS. 3 and 4.

The base plate 74 aligns the leads for filtered connections in the sub-enclosure section 40, and includes through holes 76a and 76b for the filtered connector 48, and through holes 78a and 78b for input and output leads of the filters 50. The through holes 79, for the pins 52, allow the base plate 74 to pass from a clean side to a noisy side of the PCB without degrading shielding performance of a noise suppression device. As described above, the spacing of the pins 52 is preferably below a maximum allowed spacing for the noise frequencies to be suppressed.

FIGS. 3-6 relate to embodiments of the invention in which a divider, comprising the pins 52, extends through a PCB. However, the invention is in no way limited to such dividers. A divider preferably electrically extends into or through the PCB, but need not physically extend into or through the PCB.

For example, the holes 68 are plated or stitched as shown at 70, such that electrical contact between the conductive plate 42 and a conductive plating on the opposite surface 72 or an intermediate layer of the PCB 66 may be established with pins or other structures that do not necessarily extend through, or even into, the PCB 66.

In one embodiment, the divider includes surface-mount components such as surface-mount pins or “feet” that extend onto the surface of a PCB to mount the conductive plate to the PCB. The surface-mount pins are preferably in electrical contact with conductive through hole plating such as shown at 70 in FIG. 5, or “vias” in the PCB. The vias are in turn preferably in electrical contact with conductive plating on an opposite surface of the PCB or an intermediate conductive layer of the PCB between its surfaces. This type of divider thereby electrically extends into or through the PCB without physically extending into the PCB.

It will be apparent from the foregoing that through hole pins and surface-mount pins represent two extreme cases of divider structure. Embodiments of the invention in which the divider physically extends into the PCB to an extent between these extremes are also contemplated.

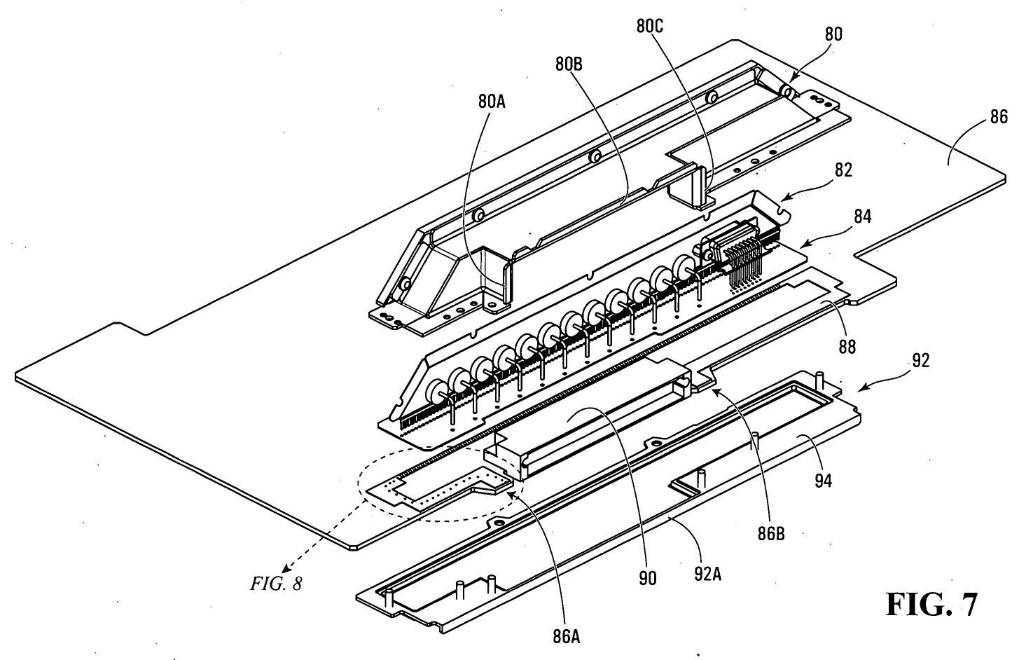

FIG. 7 is an exploded view of a noise suppression device according to a further embodiment of the invention. The noise suppression device in FIG. 7 includes sub-enclosure portions 80, 82, and 92, and is intended to be mounted along an edge of a PCB 86. The sub-enclosure sections 80 and 82 are substantially similar to the sub-enclosure sections 10 and 40 described above. The sub-enclosure section 82 is preferably first assembled with a base plate 84 to maintain lead alignment for drop-in assembly of the sub-enclosure section 82 with the PCB 86.

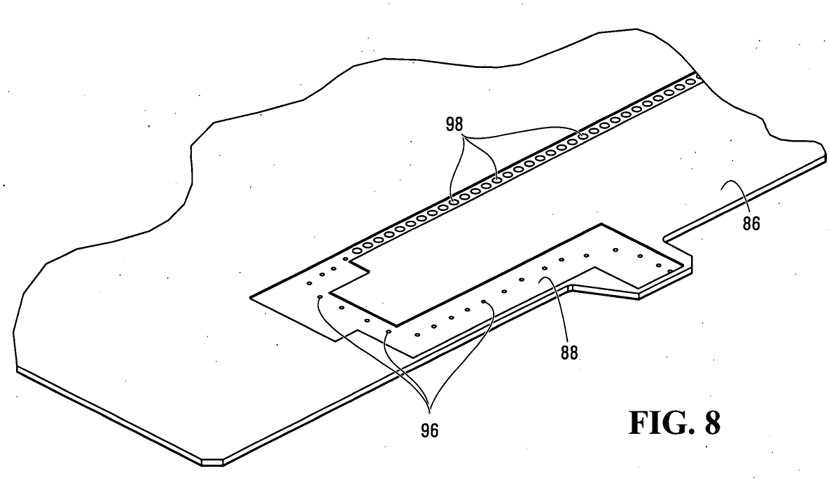

As shown in detail in FIG. 8, which is an expanded view of the section 8-8 in FIG. 7, the PCB 86 includes ground conductor plating 88, preferably copper plating. The PCB 86 also includes plated through holes 96 and 98, which provide an electrical connection between the ground conductor plating 88 and similar ground conductor plating on an opposite side (not shown) of the PCB 86. The through holes 98 also receive the pins on the sub-enclosure section 82, as described above. The through holes 96 and 98 may be of different sizes, and the through holes 96 may be designed as vias since they do not receive the pins of the sub-enclosure section 82 in the illustrated embodiment. As will be appreciated by those skilled in the art, the ground conductor plating 88 is electrically connected to ground.

Referring again to FIG. 7, it can be seen that although the pins of the sub-enclosure section 82 extend into or through the PCB 86 to divide the PCB 86 into clean and noisy areas when the sub-enclosure section 82 is assembled to the PCB 86, the PCB 86 structurally remains a single board.

During manufacturing of a PCB, through-hole components are typically placed on a substrate such that pins extend into cooperating through holes on the PCB substrate and are then soldered into the through holes. The sub-enclosure section 82 is preferably assembled and soldered to the PCB 86 along with other drop-in components (not shown). The pins on the sub-enclosure section 82 thereby extend through the PCB 86 and are in electrical contact with the ground conductor plating 88, as well as any ground conductor plating on the opposite side of the PCB 86. This simplifies the manufacturing process in that such typical elements as a conductive gasket and separate fasteners are not needed to assemble the sub-enclosure section 82 to the PCB 86. In a further preferred embodiment, integral through hole stitching as described above is performed during a soldering stage of PCB manufacturing.

The slots in the flanges of the sub-enclosure section 82 are for receiving or accommodating fasteners, as described above. As will be apparent from FIG. 7, the slots provide a further advantage during PCB manufacturing. In particular, the fasteners may be carried by the sub-enclosure section 80 and the sub-enclosure section 80, with the fasteners, can be placed on the PCB 86 in a vertical direction relative to the surface of the PCB 86 after the sub-enclosure section 82 has been assembled to the PCB 86. For example, according to one embodiment, screws are placed in bores in the sub-enclosure section 80, clamps are placed on the screws, or alternatively the clamps and screws are provided as an integrated fastener, a conductive gasket is applied to surfaces of the sub-enclosure section 80 that mate with the sub-enclosure section 82, and the sub-enclosure section 80 is placed on and fastened to the circuit board 86 such that the screws are received in the slots of the sub-enclosure section 82 and the clamps extend over the flanges of the sub-enclosure section 82. The sub-enclosure sections 80 and 82 are then attached by tightening the screws to close the clamps. Each clamp extends over the sub-enclosure section 82 to “sandwich” the sub-enclosure section 82 between a portion of the clamp and the sub-enclosure section 80. Electrical connection between the sub-enclosure section 80 and the ground conductor plating 88 is either through direct physical contact or a conductive gasket.

The portion of the PCB 86 bordered by the ground conductor plating 88 and partially enclosed by the sub-enclosure sections 80 and 82 may be either the clean side or the noisy side of the noise suppression device. For example, in one embodiment, the connector 90 receives noisy electrical input signals from an external device. The connector 90 is partially enclosed by the sub-enclosure sections 80 and 82 and the input signals are filtered by signal filters in the sub-enclosure section 82 before being transmitted to the clean side.

In FIG. 7, it is assumed that PCB component leads, including those for the filters and the filtered connection of the sub-enclosure section 82, extend into through holes in a PCB substrate to an opposite side of the substrate. Thus, the opposite side of the PCB 86 may include leads that carry clean electrical signals and leads that carry noisy electrical signals. In order to suppress radiated noise generated by the noisy electrical signals or leads, a further sub-enclosure section 92 for mounting on the opposite side of the PCB 86 is provided. The sub-enclosure section 92 is a stamped metal or other type of conductive plate having a conductive gasket 94 for establishing an electrical connection between the conductive plate and ground copper plating on the opposite surface of the PCB 86. The sub-enclosure section 92 at least partially encloses a portion of the opposite surface of the PCB 86. In FIG. 7, the sub-enclosure section 92 encloses the noisy side on the opposite surface of the PCB 86, which underlies the section of the PCB 86 that is at least partially enclosed by the sub-enclosure sections 80 and 82.

It should be appreciated that the sub-enclosure section 92 is preferred where PCB components of the enclosed portion of the PCB 86, or leads associated with such components, extend to the opposite side of the PCB 86. If these PCB components are surface-mount components for example, then the ground conductive plating on the opposite side of the PCB 86 preferably covers an underside of the enclosed portion, thereby eliminating the separate sub-enclosure section 92.

Although only the connector 90 is shown in an enclosed portion of the PCB 86, those skilled in the art will appreciate that other PCB components that generate or transmit noise, or alternatively components that are to be protected from such noise, are located in an enclosed section of a PCB in other embodiments. It should also be appreciated that a PCB may include more than one noise suppression device, to provide different noisy and clean levels or to protect different components, for instance.

To ensure a highly continuous conductive contact through the mating surfaces formed by sub-enclosure section 82, the PCB 86, and the sub-enclosure section 92, and their respective gaskets, an embodiment of the invention includes a PCB technique commonly referred as edge plating. This edge plating 86A and 86B when coplanar to flanges 80A, 80B, 80C, and 92A, forms a near-contiguous conductive surface that can mate to another sub-enclosure section to substantially enclose noisy or clean PCB components on PCB 86.

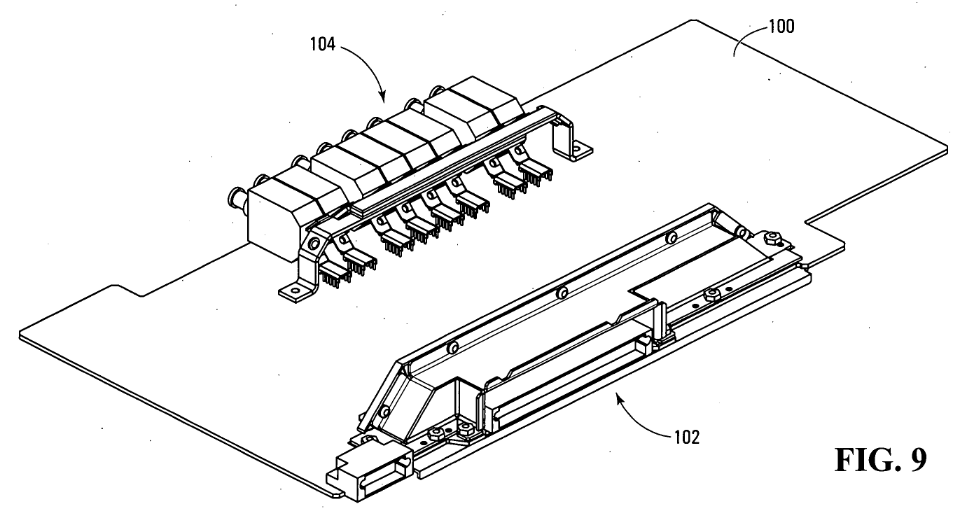

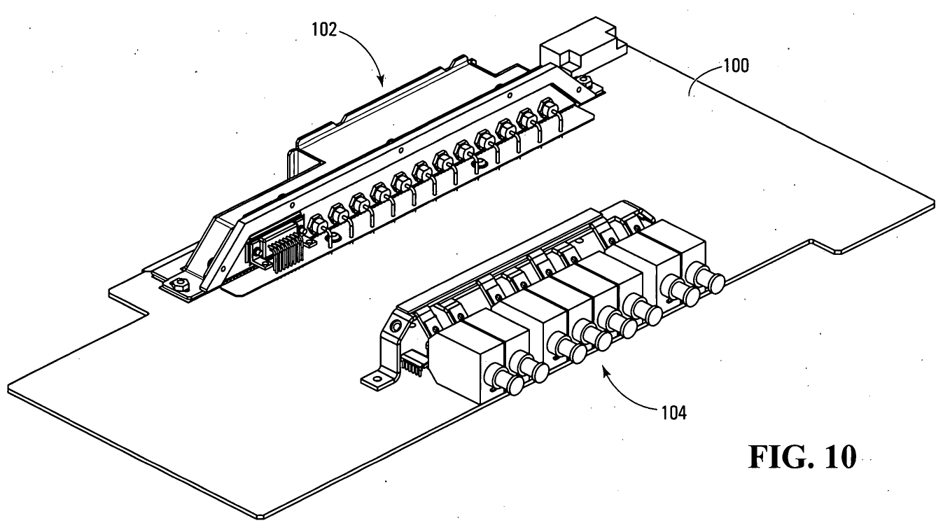

FIGS. 9 and 10 are isometric views of a PCB having a noise suppression device in accordance with an embodiment of the invention. The PCB 100 includes a noise suppression device 102 and a bank of circuit breakers 104 to which external physical access is to be provided. Clearly, the noise suppression device 102, by partitioning the PCB 100 into clean and noisy sides, provides virtually unobstructed access to the circuit breakers 104. Physical access to the circuit breakers 104, as well as any other components on a remainder of the PCB 100 outside a portion of the PCB 100 enclosed by a sub-enclosure of the noise suppression device 102, does not require openings in the sub-enclosure.

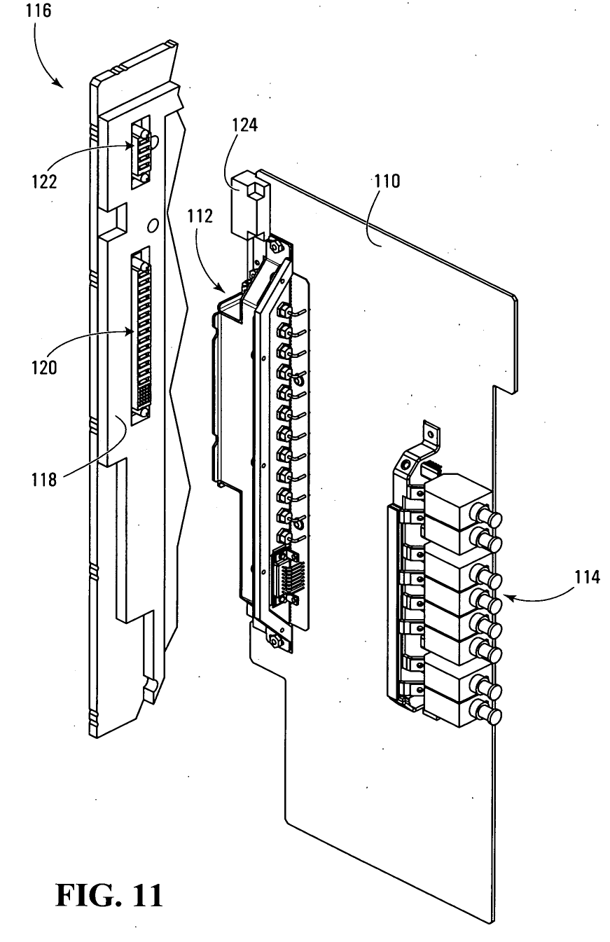

FIG. 11 is an isometric view of a backplane element and a PCB carrying a noise suppression device according to an embodiment of the invention. In FIG. 11, the backplane element 116 includes a conductive gasket 118 that is electrically connected to ground, through a conductive plate or ground conductor plating, for example. The connectors 120 and 122 interface with corresponding connectors on the PCB 110, one of which is shown at 124. As in FIGS. 9 and 10, the PCB 110 includes a noise suppression device 112 and a bank of circuit breakers 114 as examples of PCB components.

The PCB 110 is configured to operate in conjunction with an external device through the backplane element 116. The backplane element 116 may be connected to the external device or form a part of the external device. In one embodiment, the PCB 110 or a device incorporating the PCB 110 is adapted for insertion into a rack or other holder for blind mating with the backplane element 116. When placed in an operative position with the backplane element, the connectors 120 and 122 connect to corresponding connectors on the PCB 110, and the sub-enclosure of the noise-suppression device 112 is also in electrical contact with a grounded conductor on the backplane element 116 through the conductive gasket 118. The grounded conductor on the backplane element may thus be considered a further sub-enclosure element of the noise suppression device 112.

In this manner, a section of the PCB 112 may be substantially enclosed within a sub-enclosure of the noise suppression device 112. The sub-enclosure may include sub-enclosure sections for placement on both surfaces of the PCB 110 and on an external device such as the backplane element 116.

The connector 124 illustrates the fact that a noise suppression device on a PCB in no way precludes the implementation of conventional components on the same PCB. In FIG. 11, the connector 120 enters an enclosed portion of the PCB 110, whereas the connector 122 interfaces with a connector 124 that is outside the enclosed area.

It will be particularly evident from FIGS. 7-11 that many different configurations of a noise suppression device are possible in accordance with aspects of the invention. A noise suppression device according to aspects of the invention suppresses both conducted noise and radiated noise. A sub-enclosure of a noise suppression device encloses a section of a PCB to different degrees ranging from partial enclosure to substantially complete enclosure, depending upon the level of noise suppression desired. A sub-enclosure comprising sections such as 80 and 82 suppresses radiated noise in both directions, into and out of an enclosed section of a PCB, owing to the reciprocal nature of suppression devices. In certain embodiments, these sections may be fashioned to provide different degrees of suppression in each direction. The addition of further sections such as 92 or a ground conductor on an opposite side of a PCB provides more effective radiated noise suppression. Substantially complete enclosure of a portion of a PCB, with underside and backplane sub-enclosure sections, for example, provides an even higher level of radiated noise suppression.

Similarly, the extent to which a divider surrounds an enclosed portion of a PCB also affects noise suppression properties. As described above, a divider effectively extends a conductive barrier through a PCB. Therefore, a divider may extend through a PCB along only a segment of an edge of an enclosed section or along an entire perimeter of the enclosed section. In FIG. 7, the pins on the sub-enclosure section 82 provide a most effective radiated noise suppression function in a direction of the majority of the remainder of the PCB 86, which may be sufficient in many applications of a noise suppression device. Other applications may warrant a more extensive divider.

What has been described is merely illustrative of the application of the principles of the invention. Other arrangements and methods can be implemented by those skilled in the art without departing from the spirit and scope of the present invention.

For example, a PCB may include more than one noise suppression device. A sub-enclosure in a noise suppression device may also include a plurality of enclosed sections, such as a first enclosed section for suppression of radiated noise only, and a second enclosed section for suppression of both radiated and conducted noise. In this case, signal filters are included only in a part of the sub-enclosure associated with the second enclosed section.

In addition, although signal filters have been shown in the drawings in only one wall of one section of a sub-enclosure, signal filters may be provided in any or all walls of a sub-enclosure, depending upon PCB layout.

1. A noise suppression device for a printed circuit board (PCB) comprising:
an electrically conductive sub-enclosure configured to at least partially enclose a portion of the PCB;
a divider configured to extend electrically into a surface of the PCB along an edge of the at least partially enclosed portion; and
a plurality of electrical signal filters mounted on the sub-enclosure.

2. The noise suppression device of claim 1, wherein the divider is integrated with the sub-enclosure.

3. The noise suppression device of claim 1, wherein the sub-enclosure comprises a plurality of sub-enclosure sections.

4. The noise suppression device of claim 3, wherein the divider is integrated with one of the plurality of sub-enclosure sections.

5. The noise suppression device of claim 4, wherein the divider comprises a plurality of divider sections integrated with respective ones of the plurality of sub-enclosure sections.

6. The noise suppression device of claim 1, wherein the plurality of electrical signal filters comprises power filters.

7. The noise suppression device of claim 1, wherein the plurality of signal filters comprises a filtered connector.

8. The noise suppression device of claim 1, wherein the sub-enclosure is further configured to partition the PCB into a noisy side of the noise suppression device and a clean side of the noise suppression device and to shield the clean side from radiated noise generated or transmitted by the noisy side.

9. The noise suppression device of claim 8, wherein the at least partially enclosed portion comprises the clean side.

10. The noise suppression device of claim 9, wherein the plurality of electrical signal filters receive electrical signals from the noisy side, filter noise components from the electrical signals to generate filtered signals, and output the filtered signals to the clean side.

11. The noise suppression device of claim 8, wherein the at least partially enclosed portion comprises the noisy side.

12. The noise suppression device of claim 11, wherein the noisy and clean sides comprise signal lines.

13. The noise suppression device of claim 11, wherein the noisy and clean sides further comprise electronic components.

14. The noise suppression device of claim 1, wherein the sub-enclosure is surface mounted to the PCB, and wherein the divider comprises a surface mounted component in electrical contact with conductive material in a plurality of through holes in the PCB.

15. The noise suppression device of claim 1, wherein the divider extends into the surface of the PCB along an entire perimeter of the at least partially enclosed portion.

16. The noise suppression device of claim 1, wherein the divider comprises a plurality of pins, and wherein spacings between pins are less than a maximum spacing based on a wavelength of radiated noise to be suppressed.

17. The noise suppression device of claim 16, wherein the pins comprise through hole pins.

18. The noise suppression device of claim 16, wherein the pins comprise compliant pins.

19. The noise suppression device of claim 16, wherein the PCB comprises a plurality of through holes for receiving the plurality of pins.

20. The noise suppression device of claim 19, wherein the plurality of through holes are plated with a conductive material.

21. The noise suppression device of claim 20, wherein the PCB further comprises conductive surface plating on a first surface thereof in electrical contact with the sub-enclosure and the through holes.

22. The noise suppression device of claim 21, further comprising a conductive gasket for providing the electrical contact between the sub-enclosure and the conductive surface plating.

23. The noise suppression device of claim 21, wherein the PCB further comprises conductive surface plating on a second surface thereof opposite the first surface and in electrical contact with the conductive surface plating on the first surface.

24. The noise suppression device of claim 23, wherein the sub-enclosure comprises a sub-enclosure section for placement on the first surface in electrical contact with the conductive surface plating on the first surface.

25. The noise suppression device of claim 24, wherein the PCB further comprises edge plating, and wherein the edge plating and the sub-enclosure section for placement on the first surface provide a substantially continuous conductive surface when the sub-enclosure section is placed on the first surface.

26. The noise suppression device of claim 25, further comprising a second conductive surface for contacting the substantially continuous conductive surface to further enclose the at least partially enclosed section.

27. The noise suppression device of claim 24, wherein the sub-enclosure further comprises a sub-enclosure section for placement on the second surface in electrical contact with the conductive surface plating on the second surface.

28. The noise suppression device of claim 27, further comprising a conductive gasket for providing the electrical contact between the sub-enclosure section for placement on the second surface and the conductive surface plating on the second surface.

29. The noise suppression device of claim 28, wherein the PCB further comprises edge plating, and wherein the edge plating and the sub-enclosure section for placement on the second surface provide a substantially continuous conductive surface when the sub-enclosure section is placed on the second surface.

30. The noise suppression device of claim 29, further comprising a second conductive surface for contacting the substantially continuous conductive surface to further enclose the at least partially enclosed section.

31. The noise suppression device of claim 3, wherein the plurality of sub-enclosure sections includes sub-enclosure sections for placement on opposite surfaces of the PCB in electrical contact with respective conductive platings on the opposite surfaces.

32. A printed circuit board (PCB) comprising the noise suppression device of claim 1.

33. A printed circuit board (PCB) comprising a plurality of noise suppression devices according to claim 1.

34. A conductive plate for use with a conductive sub-enclosure section for at least partially enclosing a section of a printed circuit board (PCB) and for connection to a suitable RF reference potential to suppress radiated noise, the conductive plate comprising a divider configured to extend through the PCB to divide the at least partially enclosed section from a remainder of the PCB and having openings for holding signal filters for suppressing conducted noise in electrical signals.

35. The conductive plate of claim 34, wherein the sub-enclosure section defines an interior cavity, and wherein the conductive plate is further configured for attachment to the sub-enclosure section to partially close the interior cavity.

36. The conductive plate of claim 35, wherein the conductive plate and the sub-enclosure section comprise flanges for receiving fasteners to attach the conductive plate to the sub-enclosure section.

37. The conductive plate of claim 36, wherein the flanges on the conductive plate have slots for receiving the fasteners.

38. The conductive plate of claim 37, wherein the flanges on the sub-enclosure section have bores for receiving the fasteners.

39. The conductive plate of claim 36, wherein a conductive gasket is applied to the flanges of the sub-enclosure section to provide a highly RF conductive contact between the sub-enclosure section and the conductive plate.

40. The conductive plate of claim 34, wherein the divider comprises a plurality of pins for extending into through holes in the PCB, wherein the pins are separated by gaps of a size less than a maximum opening size for suppressing the radiated noise.

41. The conductive plate of claim 34, further comprising a conductive coating on each of the signal filters overlapping the openings.

42. The conductive plate of claim 34, wherein the signal filters comprise conductive bushings.

43. The conductive plate of claim 41, wherein the signal filters include a filtered connector.

44. The conductive plate of claim 43, wherein the filtered connector includes an EMI gasket to ensure a highly conductive contact to the conductive plate.

45. The conductive plate of claim 34, electrically connected to the conductive sub-enclosure section to form a conductive barrier for extending electrically through the PCB.

46. A device for suppressing noise on a printed circuit board (PCB), comprising:
means for at least partially enclosing a portion of the PCB;
means for dividing the PCB into a noisy region and a clean region, the means for dividing extending electrically into a surface of the PCB; and
means for filtering electrical signals to be transmitted from the noisy region to the clean region.

47. The device of claim 46, wherein the means for dividing extends through the PCB from a first surface of the PCB to a second opposite surface of the PCB.

48. The device of claim 46, wherein the means for at least partially enclosing comprises a plurality of conductive sub-enclosure sections for mounting on a plurality of surfaces of the PCB.

49. The device of claim 48, wherein the means for at least partially enclosing further comprises a sub-enclosure section for mounting to an external device in conjunction with which the PCB is configured to operate.

50. A printed circuit board (PCB) comprising:
an RF reference plane conductor; and
a noise suppression device in electrical contact with the RF reference plane conductor, comprising a conductive sub-enclosure at least partially enclosing a portion of the PCB and forming a conductive barrier extending through the PCB, and a plurality of filters for filtering electrical signals.

51. The PCB of claim 50, comprising a plurality of the noise suppression devices.

52. A method of manufacturing a printed circuit board (PCB) comprising:
placing drop-in components on a PCB substrate;
placing a conductive divider on the PCB substrate to divide the PCB into a plurality of areas and configured for use with a conductive sub-enclosure to at least partially enclose one of the plurality of areas; and
soldering the drop-in components and the conductive divider onto the PCB substrate.

53. The method of claim 52, further comprising:
placing the conductive sub-enclosure on the PCB substrate; and
attaching the conductive sub-enclosure to the PCB substrate and to the conductive divider.

54. The method of claim 52, wherein the sub-enclosure comprises a plurality of sub-enclosure sections, and wherein the divider is integrated with one of the plurality of sub-enclosure sections.

55. The method of claim 54, wherein the one sub-enclosure section carries a plurality of signal filters having leads, wherein the method further comprises assembling the one sub-enclosure section with a base plate, the conductive divider and the leads extending through the base plate, and wherein placing the conductive divider on the PCB substrate comprises placing the one sub-enclosure section and the base plate on the PCB substrate.
